(19) United States
(12) Patent Application Publication
(10) Pub. No.: US 2025/0076763 A1
(43) Pub. Date: Mar. 6, 2025

(54) PHOTOSENSITIVE RESIN LAMINATE AND APPLICATION THEREOF

(71) Applicant: CHANG CHUN PLASTICS CO., LTD., TAIPEI CITY (TW)

(72) Inventors: ZIH-I CHUANG, Taipei City (TW); YUN-JUNG WU, Taipei City (TW); E-MING HO, Taipei City (TW)

(21) Appl. No.: 18/445,668

(22) Filed: Feb. 28, 2024

Related U.S. Application Data
(60) Provisional application No. 63/536,189, filed on Sep. 1, 2023.

(30) Foreign Application Priority Data
Jan. 4, 2024 (TW) 113100429

(51) Int. Cl. G03F 7/095

(52) U.S. Cl. CPC G03F 7/0955

(57) ABSTRACT

A photosensitive resin laminate and application thereof are provided. The photosensitive resin laminate consists of two or more photosensitive resin layers and includes a second component, wherein: when the photosensitive resin laminate is characterized by gas chromatography with added toluene as an internal standard, an elution peak of the second component is at a retention time ranging from 0.55 min to 1.30 min, an elution peak of the added toluene is at a retention time ranging from 1.32 min to 1.65 min, and the following formula is satisfied:

$$\frac{\frac{\begin{matrix}Area of the elution peak \\ of the second component\end{matrix}}{\begin{matrix}Area of the elution peak \\ of the added toluene\end{matrix}} \times \begin{matrix}Amount of the \\ added toluene\end{matrix}}{Mass of the photosensitive resin laminate} \times 100 \% = 0.1 \% - 7. \% ,$$

and wherein the amount of the added toluene and the mass of the photosensitive resin laminate are in grams (g); and the photosensitive resin laminate has a total thickness of 100 μm to 600 μm.

### CLAIM FOR PRIORITY

This application claims the benefits of U.S. Provisional Patent Application No. 63/536,189 filed on Sep. 1, 2023 and Taiwan Patent Application No. 113100429 filed on Jan. 4, 2024, the subject matters of which are incorporated herein in their entirety by reference.

### BACKGROUND OF THE INVENTION

### Field of the Invention

The present application provides a photosensitive resin laminate, particularly a photosensitive resin laminate with high total thickness, and applications of the photosensitive resin laminate.

### Descriptions of the Related Art

Photosensitive resin films undergo chemical changes after exposure to light and are utilized as photoresist films in various electronic fields. Depending on the changes after light exposure, photoresist films can be categorized as positive and negative. In positive photoresist films, the parts exposed to light dissolve during development, leaving behind the unexposed parts. In negative photoresist films, the parts not exposed to light dissolve during development, leaving behind the parts exposed to light.

In the printed circuit boards (PCBs) industry, photoresist films are utilized in the etching or electroplating procedures to create circuit patterns. Due to the increasing complexity and size of electronic components, a thick photoresist film with a high depth-to-width ratio is required in the printed circuit boards industry. However, conventional photoresist films often exhibit poor adhesion, or contains bubbles or wrinkles, leading to defects in subsequent electroplating or etching processes.

### SUMMARY OF THE INVENTION

Given the aforementioned technical problems, the present application aims to provide a solution for improving adhesion, storage properties, and operability of a photoresist film. Studies have found that these technical problems can be addressed by a photosensitive resin laminate consisting of multiple photosensitive resin layers.

Therefore, an objective of the present application is to provide a photosensitive resin laminate, which consists of two or more photosensitive resin layers and comprises a second component, wherein:
when the photosensitive resin laminate is characterized by gas chromatography with added toluene as an internal standard, an elution peak of the second component is at a retention time ranging from 0.55 min to 1.30 min, an elution peak of the added toluene is at a retention time ranging from 1.32 min to 1.65 min, and the following formula is satisfied:

$$\frac{\frac{\begin{matrix}Area of the elution peak \\ of the second component\end{matrix}}{\begin{matrix}Area of the elution peak \\ of the added toluene\end{matrix}} \times \begin{matrix}Amount of the \\ added toluene\end{matrix}}{Mass of the photosensitive resin laminate} \times 100 \% = 0.1 \% - 7. \% ,$$

wherein the amount of the added toluene and the mass of the photosensitive resin laminate are in grams (g); and
the photosensitive resin laminate has a total thickness of 100 μm to 600 μm.

In some embodiments of the present application, the gas chromatography is performed by dissolving the photosensitive resin laminate in propylene glycol methyl ether with added toluene as an internal standard to form a solution, and testing the solution under the following conditions: a stainless steel column with a column length of 3 meters, an outer diameter of ⅛ inches and a column wall thickness of 0.02 inches is used; a porous polymer stationary phase is used as a filler; helium with a flow rate of 20 mL/min and a supply pressure of 5 kgf/cm² serves as a carrier gas; a stepwise heating condition is applied, which sequentially includes maintaining at 80° C. for 0.1 min, heating from 80° C. to 96° C. at a heating rate of 4° C./min, heating from 96° C. to 135° C. at a heating rate of 10° C./min, and maintaining at 135° C. for 2 min; a temperature at an injection port is 180° C.; an injection volume of the solution is 3 μL; and a thermal conductivity detector at 200° C. is used.

In some embodiments of the present application, the two or more photosensitive resin layers each independently have a thickness of 50 μm to 300 μm.

In some embodiments of the present application, the photosensitive resin laminate consists of two to four photosensitive resin layers.

In some embodiments of the present application, the two or more photosensitive resin layers are each independently dry films.

In some embodiments of the present application, the two or more photosensitive resin layers each independently comprise: (A) an alkali-soluble polymer, (B) a component of ethylenically unsaturated compound(s), and (C) a photopolymerization initiator.

In some embodiments of the present application, the component (B) of ethylenically unsaturated compound(s) comprises one or more bifunctional acrylate-based compounds.

In some embodiments of the present application, based on the weight of the component (B) of ethylenically unsaturated compound(s), the amount of the bifunctional acrylate-based compounds is 60 wt % or more.

Another objective of the present application is to provide a composite laminate, which comprises the aforementioned photosensitive resin laminate and a non-photosensitive resin film on at least one surface of the photosensitive resin laminate.

In some embodiments of the present application, the non-photosensitive resin film is selected from the group consisting of a polyethylene terephthalate film, a polyolefin film, and a composite thereof.

To render the above objectives, technical features, and advantages of the present application more apparent, the present application will be described in detail with reference to some specific embodiments hereinafter.

### BRIEF DESCRIPTION OF THE DRAWINGS

Not applicable.

### DESCRIPTION OF THE EMBODIMENTS

Some specific embodiments of the present application will be described in detail. However, the present application may be embodied in various embodiments and should not be limited to the embodiments described in the specification.

Unless additionally explained, the expressions “a,” “the,” or the like, as recited in the specification and the claims, should include both the singular and plural forms.

Unless additionally explained, the expressions “first,” “second,” or the like, as recited in the specification and the claims, are used solely to distinguish the illustrated elements or components without special meanings. These expressions are not used to represent any priority.

Unless additionally explained, the term “(meth)acrylic,” “(meth)acrylate,” or the like, is intended to cover both species containing and not containing the group in the parentheses. For example, “(meth)acrylic acid” intends to cover both acrylic acid and methacrylic acid, and “methyl (meth)acrylate” intends to cover both methyl acrylate and methyl methacrylate.

In the specification and the claims, the weight average molecular weight (Mw) is measured by gel permeation chromatography (GPC) and calculated by comparing it with a standard sample. The unit of the weight average molecular weight (Mw) is “g/mol”.

The primary advantage of the present application over prior art lies in providing a high-thickness photosensitive resin laminate with excellent adhesion, storage properties and operability by controlling the gas chromatography property of the photosensitive resin laminate. Details regarding the photosensitive resin laminate and its applications are provided below.

### 1. PHOTOSENSITIVE RESIN LAMINATE

The photosensitive resin laminate of the present application consists of two or more photosensitive resin layers and comprises a second component. The second composition can be comprised in the photosensitive resin layers of the photosensitive resin laminate. In some embodiments of the present application, the photosensitive resin laminate consists of two to four photosensitive resin layers, and each of the photosensitive resin layers comprises the second component.

In some embodiments of the present application, the photosensitive resin laminate is essentially free of toluene. That is, based on the total weight of the photosensitive resin laminate, the amount of toluene is 0.5 wt % or less. For example, based on the total weight of the photosensitive resin laminate, the amount of toluene can be 0.5 wt %, 0.45 wt %, 0.4 wt %, 0.35 wt %, 0.3 wt %, 0.25 wt %, 0.2 wt %, 0.15 wt %, 0.1 wt %, 0.05 wt %, or 0.01 wt %. In some embodiments of the present application, the photosensitive resin laminate does not contain toluene.

The photosensitive resin laminate of the present application can be used as a positive photoresist film or a negative photoresist film. In some embodiments of the present application, the photosensitive resin laminate of the present application is used as a negative photoresist film. That is, after light exposure of the photoresist film, the parts that were not exposed to light dissolve away during development, leaving behind the parts exposed to light.

The total thickness of the photosensitive resin laminate of the present application ranges from 100 μm to 600 μm. For example, the total thickness of the photosensitive resin laminate of the present application can be 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, 300 μm, 310 μm, 320 μm, 330 μm, 340 μm, 350 μm, 360 μm, 370 μm, 380 μm, 390 μm, 400 μm, 410 μm, 420 μm, 430 μm, 440 μm, 450 μm, 460 μm, 470 μm, 480 μm, 490 μm, 500 μm, 510 μm, 520 μm, 530 μm, 540 μm, 550 μm, 560 μm, 570 μm, 580 μm, 590 μm, or 600 μm, or within a range between any two of the values described herein. As the thickness of the photosensitive resin laminate increases, so does the achievable thickness for plating a metal conductive layer when using the photosensitive resin laminate as a photoresist film. Therefore, the photosensitive resin laminate is particularly suitable for 2.5D and 3D integrated circuit packaging and is useful in patterning prior to the plating of the conductive layer.

### 1.1. Gas Chromatography Property of Photosensitive Resin Laminate

The photosensitive resin laminate of the present application has a specific gas chromatography property. Specifically, when the photosensitive resin laminate is characterized by gas chromatography with added toluene as an internal standard, an elution peak of the second component is at a retention time ranging from 0.55 min to 1.30 min, an elution peak of the added toluene is at a retention time ranging from 1.32 min to 1.65 min, and the following formula is satisfied:

$$\frac{\frac{\begin{matrix}Area of the elution peak \\ of the second component\end{matrix}}{\begin{matrix}Area of the elution peak \\ of the added toluene\end{matrix}} \times \begin{matrix}Amount of the \\ added toluene\end{matrix}}{Mass of the photosensitive resin laminate} \times 100 \% = 0.1 \% - 7. \% ,$$

wherein the amount of the added toluene and the mass of the photosensitive resin laminate are in grams (g).

In the above formula, “0.1%-7.0%” means that the value obtained from calculating the left-hand side of the equation can range from 0.1% to 7.0%. For example, in the formula above, the value obtained from calculating the left hand side of the equation can be 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.1%, 5.2%, 5.3%, 5.4%, 5.5%, 5.6%, 5.7%, 5.8%, 5.9%, 6.0%, 6.1%, 6.2%, 6.3%, 6.4%, 6.5%, 6.6%, 6.7%, 6.8%, 6.9%, or 7.0%, or within a range between any two of the values described herein.

The gas chromatography is performed by dissolving the photosensitive resin laminate in propylene glycol methyl ether with added toluene as an internal standard to form a solution, and testing the solution under the following conditions: a stainless steel column with a column length of 3 meters, an outer diameter of ⅛ inches and a column wall thickness of 0.02 inches is used; a porous polymer stationary phase is used as a filler; helium with a flow rate of 20 mL/min and a supply pressure of 5 kgf/cm² serves as a carrier gas; a stepwise heating condition is applied, which sequentially includes maintaining at 80° C. for 0.1 min, heating from 80° C. to 96° C. at a heating rate of 4° C./min, heating from 96° C. to 135° C. at a heating rate of 10° C./min, and maintaining at 135° C. for 2 min; a temperature at an injection port is 180° C.; an injection volume of the solution is 3 μL; and a thermal conductivity detector at 200° C. is used. In the aforementioned testing conditions, the porous polymer stationary phase can be a column with a model number of CRS BX-10 (available from Heng Yi Enterprise Company).

The mass of the photosensitive resin laminate used in the gas chromatography can range from 11 g to 19.5 g, and the amount of added toluene used in the gas chromatography can range from 0.45 g to 0.55 g. For example, the mass of the photosensitive resin laminate can be 11 g, 11.5 g, 12 g, 12.5 g, 13 g, 13.5 g, 14 g, 14.5 g, 15 g, 15.5 g, 16 g, 16.5 g, 17 g, 17.5 g, 18 g, 18.5 g, or 19 g, or within a range between any two of the values described herein. The amount of the added toluene can be 0.45 g, 0.46 g, 0.47 g, 0.48 g, 0.49 g, 0.50 g, 0.51 g, 0.52 g, 0.53 g, 0.54 g, or 0.55 g, or within a range between any two of the values described herein. In the gas chromatography, the mass of the photosensitive resin laminate used is preferably 25 to 35 times that of the added toluene achieve a better signal-to-noise ratio. In some embodiments of the present application, the mass of the photosensitive resin laminate used in the gas chromatography is 15 g, and the amount of added toluene ranges from 0.50 g to 0.53 g.

The mass of propylene glycol methyl ether used in the gas chromatography can range from 55 g to 65 g. For example, the mass of propylene glycol methyl ether used in the gas chromatography can be 55 g, 56 g, 57 g, 58 g, 59 g, 60 g, 61 g, 62 g, 63 g, 64 g, or 65 g, or within a range between any two of the values described herein. In the gas chromatography, the retention time of propylene glycol methyl ether is later than the retention time of toluene. In some embodiments of the present application, the elution peak of propylene glycol methyl ether corresponds to a retention time of 1.9 min to 6.9 min.

### 1.2. Photosensitive Resin Layer

The photosensitive resin laminate of the present application can consist of two or more photosensitive resin layers. For example, the photosensitive resin laminate of the present application can consist of two, three or four photosensitive resin layers, but the present application is not limited thereto. The photosensitive resin layers can each independently have a thickness ranging from 50 μm to 300 μm. For example, the photosensitive resin layers can each independently have a thickness of 50 μm, 60 μm, 70 μm, 80 μm, 90 μm, 100 μm, 110 μm, 120 μm, 130 μm, 140μ, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, or 300 μm, or a thickness falling within a range between any two of the values described herein.

In some embodiments of the present application, the photosensitive resin layers are each independently dry films, meaning they are photosensitive resin films with low solvent content. The term “low solvent content” refers to the amount of solvent based on the total weight of the photosensitive resin film, which ranges from 0.1 wt % to 8 wt %, more specifically 0.1 wt % to 7 wt %. Compared with ink-like or liquid wet films, dry films are less likely to flow or deform due to their low solvent content and can be attached to a substrate without additional processes such as coating or drying. Therefore, dry films are easy to control and offer good operability.

With the premise that the photosensitive resin laminate satisfies the aforementioned gas chromatography property, the composition of the two or more photosensitive resin layers forming the photosensitive resin laminate can be adjusted depending on the need. The composition of the two or more different photosensitive resin layers can be either identical or different. In some embodiments of the present application, the photosensitive resin layers each independently comprise: (A) an alkali-soluble polymer, (B) a component of ethylenically unsaturated compound(s), (C) a photopolymerization initiator, a second component, and optional additives.

### 1.2.1. (A) Alkali-Soluble Polymer

Examples of the alkali-soluble polymer include, but are not limited to, carboxyl-containing polymers such as a carboxyl-containing acrylic acid-based polymer, a carboxyl-containing vinyl aromatic-based polymer, a carboxyl-containing norbornene-based polymer, a carboxyl-containing epoxy-based polymer, a carboxyl-containing amide-based polymer, a carboxyl-containing amide epoxy-based polymer, a carboxyl-containing alkyd-based polymer, and a carboxyl-containing phenol-based polymer. The aforementioned alkali-soluble polymers can be used alone or in combination. In some embodiments of the present application, the alkali-soluble polymer is a carboxyl-containing acrylic acid-based polymer.

The alkali-soluble polymer can be, for example, obtained by polymerizing one or more carboxyl-containing polymerizable monomers, or by copolymerizing one or more carboxyl-containing polymerizable monomers with other polymerizable monomer(s) that do not contain carboxyl groups. Therefore, the alkali-soluble polymer can comprise one or more repeating units derived from carboxyl-containing polymerizable monomers, or it can comprise one or more repeating units derived from both carboxyl-containing polymerizable monomers and other polymerizable monomers.

In some embodiments of the present application, the alkali-soluble polymer has repeating units derived from at least one first polymerizable monomers and repeating units derived from at least one-second polymerizable monomers, wherein the first polymerizable monomers contain carboxyl groups. Examples of the first polymerizable monomers include, but are not limited to, (meth)acrylic acid, α-bromo(meth)acrylic acid, α-chloro(meth)acrylic acid, β-phthalimido(meth)acrylic acid, β-styryl(meth)acrylic acid, propiolic acid, fumaric acid, cinnamic acid, crotonic acid, itaconic acid, and maleic acid. The second polymerizable monomers do not contain carboxyl groups. Examples of the second polymerizable monomers include, but are not limited to, (meth)acrylate-based compounds such as methyl (meth)acrylate, ethyl (meth)acrylate, n-propyl (meth)acrylate, isopropyl (meth)acrylate, n-butyl (meth)acrylate, isobutyl (meth)acrylate, 2-ethylhexyl (meth)acrylate, tert-butyl (meth)acrylate, 2-hydroxyethyl (meth)acrylate, 2-hydroxypropyl (meth)acrylate, cyclohexyl (meth)acrylate, benzyl (meth)acrylate, 1-methyl-cyclopentyl (meth)acrylate, 1-methyl-cyclohexyl (meth)acrylate, 2-methyl-2-adamantyl (meth)acrylate, 2-ethyl-2-adamantyl (meth)acrylate, 2-butyl-2-adamantyl (meth)acrylate, tetrahydrofurfuryl methyl (meth)acrylate, dimethylamino ethyl (meth)acrylate, diethylamino ethyl (meth)acrylate, glycidyl (meth)acrylate, 2,2,2-trifluoroethyl (meth)acrylate, and 2,2,3,3-tetrafluoropropyl (meth)acrylate; (meth)acrylonitrile; vinyl ester-based compounds such as vinyl acetate and vinyl n-butylate; vinyl aromatic-based compounds such as styrene, vinyl naphthalene, 3-acetoxystyrene, 4-acetoxystyrene, vinyl toluene, and α-methyl styrene; norbornene; acrylamide; maleate-based compounds such as monomethyl maleate, monoethyl maleate, and monoisopropyl maleate; and derivatives of the forgoing polymerizable monomers. The aforementioned first polymerizable monomers and second polymerizable monomers can be used alone or in combination.

In a preferred embodiment of the present application, the alkali-soluble polymer is obtained by copolymerizing (meth)acrylic acid and one or more (meth)acrylate-based compounds, and therefore comprises repeating units derived from (meth)acrylic acid and repeating units derived from (meth)acrylate-based compounds. The weight ratio of the (meth)acrylic acid to the (meth)acrylate-based compound can be 1:20 to 1:1, more specifically 1:6 to 1:4. For example, the weight ratio of the (meth)acrylic acid to the (meth)acrylate-based compounds can be 1:20, 1:19, 1:18, 1:17, 1:16, 1:15, 1:14, 1:13, 1:12, 1:11, 1:10, 1:9, 1:8, 1:7, 1:6, 1:5, 1:4, 1:3, 1:2, or 1:1, or within a range between any two of the values described herein.

The weight average molecular weight (Mw) of the alkali-soluble polymer can range from 10,000 to 180,000, with a preferred range of 40,000 to 80,000. For example, the weight average molecular weight of the alkali-soluble polymer can be 10,000, 15,000, 20,000, 25,000, 30,000, 35,000, 40,000, 45,000, 50,000, 55,000, 60,000, 65,000, 70,000, 75,000, 80,000, 85,000, 90,000, 95,000, 100,000, 105,000, 110,000, 115,000, 120,000, 125,000, 130,000, 135,000, 140,000, 145,000, 150,000, 155,000, 160,000, 165,000, 170,000, 175,000, or 180,000, or within a range between any two of the values described herein.

The amount of the alkali-soluble polymer, based on the weight of the photosensitive resin layer to which it belongs, can independently range from 20 wt % to 85 wt %, more preferably from 40 wt % to 80 wt %, and even more preferably from 50 wt % to 75 wt %. For example, the amount of the alkali-soluble polymer, based on the weight of the photosensitive resin layer to which it belongs, can be 20 wt %, 22.5 wt %, 25 wt %, 27.5 wt %, 30 wt %, 32.5 wt %, 35 wt %, 37.5 wt %, 40 wt %, 42.5 wt %, 45 wt %, 47.5 wt %, 50 wt %, 52.5 wt %, 55 wt %, 57.5 wt %, 60 wt %, 62.5 wt %, 65 wt %, 67.5 wt %, 70 wt %, 72.5 wt %, 75 wt %, 77.5 wt %, 80 wt %, 82.5 wt %, or 85 wt %, or within a range between any two of the values described herein.

### 1.2.2. (B) Component of Ethylenically Unsaturated Compound(s)

The ethylenically unsaturated compound refers to a compound with at least one reactive ethylene functional group and is preferably a bifunctional compound with two reactive ethylene functional groups. In some embodiments of the present application, the component of ethylenically unsaturated compounds comprises a monofunctional or multifunctional acrylate-based compound and preferably comprises a bifunctional acrylate-based compound. Examples of acrylate-based compound include, but are not limited to, ethoxylated bisphenol-A dimethacrylate, trimethylolpropane triacrylate, ethoxylated trimethylolpropane triacrylate, ethoxylated bisphenol-A diacrylate, tripropylene glycol diacrylate, 1,6-hexanediol diacrylate, polypropylene glycol diacrylate, tris((meth)acryloxyisocyanate) hexamethylene isocyanurate, ethoxylated urethane di(meth)acrylate, propoxylated urethane di(meth)acrylate, ethoxylated/propoxylated urethane di(meth)acrylate, ethoxylated tris(methacryloxyisocyanate) hexamethylene isocyanurate, acrylated tris(methacryloxyisocyanate) hexamethylene isocyanurate, and ethoxylated/propoxylated tris(methacryloxyisocyanate) hexamethylene isocyanurate. Furthermore, in each photosensitive resin layer, the amount of the bifunctional acrylate-based compounds based on the weight of the component of ethylenically unsaturated compound(s) in the respective photosensitive resin layer is preferably 60 wt % or more. For example, the amount of the bifunctional acrylate-based compounds based on the weight of the component of ethylenically unsaturated compound(s) in the respective photosensitive resin layer can be 60 wt %, 62.5 wt %, 65 wt %, 67.5 wt %, 70 wt %, 72.5 wt %, 75 wt %, 77.5 wt %, 80 wt %, 82.5 wt %, 85 wt %, 87.5 wt %, 90 wt %, 92.5 wt %, 95 wt %, 97.5 wt %, or 100 wt %, or within a range between any two of the values described herein.

In some embodiments of the present application, the component of ethylenically unsaturated compound(s) comprises at least one of ethoxylated bisphenol-A dimethacrylate and trimethylolpropane triacrylate.

The amount of the component of ethylenically unsaturated compound(s) based on the weight of the photosensitive resin layer to which it belongs can range from 5 wt % to 70 wt %, more specifically from 15 wt % to 50 wt %, even more specifically from 20 wt % to 45 wt %. For example, the amount of the component of ethylenically unsaturated compound(s) based on the total weight of the photosensitive resin layer to which it belongs can be 5 wt %, 7.5 wt %, 10 wt %, 12.5 wt %, 15 wt %, 17.5 wt %, 20 wt %, 22.5 wt %, 25 wt %, 27.5 wt %, 30 wt %, 32.5 wt %, 35 wt %, 37.5 wt %, 40 wt %, 42.5 wt %, 45 wt %, 47.5 wt %, 50 wt %, 52.5 wt %, 55 wt %, 57.5 wt %, 60 wt %, 62.5 wt %, 65 wt %, 67.5 wt %, or 70 wt %, or within a range between any two of the values described herein.

### 1.2.3. (C) Photopolymerization Initiator

The photopolymerization initiator refers to a substance that can initiate polymerization reaction in the presence of light. The species of the photopolymerization initiator are not particularly limited. Examples of the photopolymerization initiator include, but are not limited to, imidazole-based compounds, ketone-based compounds, quinone-based compounds, benzoin-based or benzoin ether-based compounds, polyhalogenated compounds, triazine-based compounds, organic peroxide compounds, onium compounds, and other common photopolymerization initiators known in the art. The aforementioned photopolymerization initiators can be used alone or in combination.

Examples of the imidazole-based compounds include, but are not limited to, 2,4,6-triaryl imidazole dimer, such as 2-(o-chlorophenyl)-4,5-diphenylimidazole dimer, 2-(o-chlorophenyl)-4,5-di(m-methoxyphenyl) imidazole dimer, 2-(o-fluorophenyl)-4,5-diphenylimidazole dimer, 2-(o-methoxyphenyl)-4,5-diphenyl-4,5-triarylimidazole dimer, and 2-(p-methoxyphenyl)-4,5-diphenylimidazole dimer.

Examples of the ketone-based compounds include, but are not limited to, benzophenone, 4,4-bis(dimethylamino) benzophenone, 4-methoxy-4′-dimethylamino benzophenone, 4,4′-dimethoxy benzophenone, 4-dimethylamino benzophenone, 4-dimethylamino acetophenone, xanthone, thioxanthone, 2-chloro thioxanthone, 2,4-diethyl thioxanthone, acridone, α-hydroxy acetophenone, α-amino acetophenone, α-hydroxycycloalkyl phenone, and dialkyl acetophenone.

Examples of quinone-based compounds include, but are not limited to, camphorquinone, benzanthraquinone, 2-tert-butylanthraquinone, and 2-methylanthraquinone.

Examples of benzoin-based or benzoin ether-based compounds include, but are not limited to, benzoin methyl ether, benzoin ethyl ether, benzoin propyl ether, and benzoin phenyl ether.

Examples of polyhalogenated compounds include, but are not limited to, carbon tetrabromide, phenyl tribromomethyl sulfone, and phenyl trichloromethyl ketone.

Examples of triazine-based compounds include, but are not limited to, 2,4,6-tris(trichloromethyl)-s-triazine, 2-methoxy-4,6-bis(trichloromethyl)-s-triazine, 2-amino-4,6-bis(trichloromethyl)-s-triazine, and 2-(p-methoxystyryl)-4,6-bis(trichloromethyl)-s-triazine.

Examples of organic peroxide compounds include, but are not limited to, methyl ethyl ketone peroxide, cyclohexanone peroxide, 3,3,5-trimethyl cyclohexanone peroxide, benzoyl peroxide, di-tert-butyl isophthalate peroxide, 2,5-dimethyl-2,5-di(benzoylperoxy) hexane, tert-butyl peroxybenzoate, a,a′-bis(tert-butylperoxyisopropyl)benzene, dicumyl peroxide, and 3,3′,4,4′-tetra(tert-butylperoxycarbonyl) benzophenone.

Examples of the onium compounds include, but are not limited to, diaryliodonium salts and triarylsulfonium salts obtained from diphenyliodonium, 4,4′-dichlorodiphenyliodonium, 4,4′-dimethoxydiphenyliodonium, 4,4′-di-tert-butyldiphenyliodonium, 4-methyl-4′-isopropyldiphenyliodonium, or 3,3′-dinitrodiphenyl iodonium in combination with chloride, bromide, tetrafluoroborate, hexafluorophosphate, hexafluoroarsenate, hexafluoroantimonate, and tetrakis(pentafluorophenyl) borate, or trifluoromethanesulfonic acid.

Examples of the aforementioned other common photopolymerization initiators known in the art include, but are not limited to, fluorine, bisacylphosphine oxides, azinium compounds, organic boron compounds, phenylglyoxylate, and titanocene.

In some embodiments of the present application, the photopolymerization initiator is an imidazole-based compound or a ketone-based compound.

The amount of the photopolymerization initiator based on the weight of the photosensitive resin layer to which it belongs can range from 0.1 wt % to 15 wt %, more specifically from 0.5 wt % to 10 wt %, and even more specifically from 1 wt % to 5 wt %. For example, the amount of the photopolymerization initiator based on the weight of the photosensitive resin layer to which it belongs can be 0.1 wt %, 0.5 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, 10 wt %, 10.5 wt %, 11 wt %, 11.5 wt %, 12 wt %, 12.5 wt %, 13 wt %, 13.5 wt %, 14 wt %, 14.5 wt %, or 15 wt %, or within a range between any two of the values described herein.

### 1.2.4. Second Component

In the present application, the second component refers to a component that contributes to an elution peak at a retention time ranging from 0.55 min to 1.30 min when the photosensitive resin laminate is characterized by gas chromatography with added toluene as an internal standard. The second component can present in at least one photosensitive resin layer, preferably in every photosensitive resin layer forming the photosensitive resin laminate.

In some embodiments of the present application, the second components of photosensitive resin layers can each independently be at least one of an inert ester, ketone, ether, or alcohol with a boiling point ranging from 55° C. to 90° C. The term “inert ester, ketone, ether, or alcohol” refers to an ester, ketone, ether, or alcohol that is miscible with other components of the photosensitive resin layer but does not react with those components. For example, the second component can comprise at least one of methyl acetate, ethyl acetate, acetone, methyl ethyl ketone, methanol, ethanol, and isopropanol.

### 1.2.5. Optional Additives

With the premise that the photosensitive resin laminate satisfies the aforementioned gas chromatography property, the two or more photosensitive resin layers forming the photosensitive resin laminate can further comprise additive(s) to improve the properties of the photosensitive resin layers. Examples of additives include, but are not limited to, solvents, light absorbers, dyes, pigments, radical inhibitors, and surfactants. The aforementioned additives can be used alone or in combination.

### 1.3. Preparation of Photosensitive Resin Laminate

The preparation method of the photosensitive resin laminate is not particularly limited. Persons having ordinary skill in the art would be able to prepare the photosensitive resin laminate by referring to the specification of the subject application, especially relying on the specific illustrations in the Examples. For example, the process of preparing the aforementioned exemplary photosensitive resin laminate involves uniformly mixing the components of the photosensitive resin film, including (A) an alkali-soluble polymer, (B) a component of ethylenically unsaturated compound(s), (C) a photopolymerization initiator, a second component, and optional additive(s), using a stirrer. Subsequently, the mixture is dissolved or dispersed in a solvent to form a photosensitive solution, which is then coated onto a substrate. The coated photosensitive solution is dried to obtain a photosensitive resin layer. These steps can be repeated, optionally changing the constitution of the photosensitive solution, to obtain further photosensitive resin layers. Finally, the obtained photosensitive resin layers are stacked and pressed or adhered together to obtain a photosensitive resin laminate.

The coating method of the photosensitive solution is not particularly limited and can be any existing coating method commonly used in the field of the present application. Examples of the existing coating methods include, but are not limited to, gravure coating, reverse roll coating, die coating, air scraper coating, scraper coating, rod coating, scraper rod coating, curtain coating, knife coating, transfer roll coating, extrusion press coating, dip coating, kiss coating, spray coating, calendar coating, and extrusion coating. In some embodiments of the present application, the preferred coating methods for the photosensitive solution include scraper coating, rod coating, scraper rod coating, or die coating.

In some embodiments of the present application, to dry the photosensitive resin layer to a suitable extent, the coated photosensitive solution can be baked at a temperature ranging from 70° C. to 200° C. for 1 to 40 minutes, preferably at 100° C. to 180° C. for 1 to 40 minutes.

A detailed preparation method of the photosensitive resin laminate is illustrated in the Examples below.

### 2. APPLICATION OF PHOTOSENSITIVE RESIN LAMINATE

The photosensitive resin laminate of the present application can be used as a photoresist film and finds applications in various electronic fields. Generally, before using a photoresist film, protective films that provide protection and support functions can be applied to both surfaces of the photoresist film. This facilitates the storage of the photoresist film and protects it from contamination or damage. Similarly, protective films can be provided on the surfaces of the photosensitive resin laminate, and the protective films are preferably a non-photosensitive resin film.

Therefore, the present application also provides a composite laminate, which comprises the aforementioned photosensitive resin laminate and a non-photosensitive resin film on at least one surface of the photosensitive resin laminate. In a preferred embodiment of the present application, non-photosensitive resin films are provided on both surfaces of the photosensitive resin laminate, and the materials of the non-photosensitive resin films on the two different surfaces of the photosensitive resin laminate can be identical or different.

The type of the non-photosensitive resin film is not particularly limited and can be any conventional material known in the art. For example, the non-photosensitive resin film that can be used in the present application can be selected from the group consisting of a polyethylene terephthalate film (PET film), a polyolefin film and composites thereof. Examples of polyolefin film include, but are not limited to, a polyethylene film (PE film) and a polypropylene film (PP film), such as an oriented polypropylene film. The composite can be a composite of a polyethylene terephthalate film and a polyolefin film or a composite of different polyolefin films. In a preferred embodiment of the present application, the composite laminate comprises a PET film on one surface of the photosensitive resin laminate and a PE film on the other surface of the photosensitive resin laminate.

The preparation method of the composite laminate of the present application is not particularly limited and can encompass any method known in the art. Persons having ordinary skill in the art would be able to prepare the composite laminate by referring to the specification of the subject application. For example, the composite laminate can be prepared by stacking the non-photosensitive resin films on both surfaces of the photosensitive resin laminate to provide a superimposed object and pressing the superimposed object to obtain the composite laminate. Alternatively, the composite laminate can be prepared by forming a photosensitive resin layer between two non-photosensitive films through coating or extrusion. The non-photosensitive film on the surface of the photosensitive resin layer that will be in contact with another photosensitive resin layer is then peeled off, followed by stacking and pressing to obtain a composite laminate.

A detailed preparation method of the composite laminate is illustrated in the Examples below.

### 3. EXAMPLES

### 3.1. Testing Methods

### [Number of Layers of the Photosensitive Resin Laminate]

The prepared composite laminate is cut along the transverse direction (TD) and machine direction (MD) at an arbitrary position into a size of 10 mm×15 mm. The PE film and PET film are removed from both surfaces of the photosensitive resin laminate. The photosensitive resin laminate sample is placed on an analysis platform of a microscope (model number: Olympus MX51) with a jig, and the sample's position is adjusted to ensure the cross-section of the sample is perpendicular to the viewing direction of the objective lens. The cross-section is inspected under a fluorescence filter, a 10× objective lens (model number: MPlanFL N), and a 10× eyepiece lens. When a distinct interfacial boundary between layers is found, it indicates the sample has a laminate structure. Each identified interfacial boundary is counted to determine the number of layers of the photosensitive resin laminate (=“the number of identified interfacial boundaries+1”).

### [Gas Chromatography of the Photosensitive Resin Laminate]

The PE film and PET film of the composite laminate are removed from both surfaces of the photosensitive resin laminate. Then, the obtained photosensitive resin laminate is cut into a 15-g sample along the transverse direction (TD) and machine direction (MD) at an arbitrary position. The resulting photosensitive resin laminate sample is dissolved in 60 g of propylene glycol methyl ether, and 0.50 g to 0.53 g of toluene is added as an internal standard to form a solution. The gas chromatography is performed under the following conditions: a stainless steel column with a column length of 3 meters, an outer diameter of ⅛ inches and a column wall thickness of 0.02 inches is used; as a filler, a CRS BX-10 column (available from Heng Yi Enterprise Company) is used; helium with a flow rate of 20 mL/min and a supply pressure of 5 kgf/cm² serves as a carrier gas; a stepwise heating condition is applied, which sequentially includes maintaining at 80° C. for 0.1 min, heating from 80° C. to 96° C. at a heating rate of 4° C./min, heating from 96° C. to 135° C. at a heating rate of 10° C./min, and maintaining at 135° C. for 2 min; a temperature at an injection port is 180° C.; an injection volume of the solution is 3 μL; and a thermal conductivity detector at 200° C. is used. The analysis software Qchrom V1.2, available from Scientific Information Service Company, is used for analysis. Calculation is performed according to the following formula and the obtained value is recorded as the “calculation result of the gas chromatography”.

$$\frac{\frac{\begin{matrix}Area of the elution peak \\ of the second component\end{matrix}}{\begin{matrix}Area of the elution peak \\ of the added toluene\end{matrix}} \times \begin{matrix}Amount of the \\ added toluene\end{matrix}}{Mass of the photosensitive resin laminate} \times 100 \%$$

### [Bubble Analysis of the Photosensitive Resin Laminate]

The prepared composite laminate is cut along the transverse direction (TD) and machine direction (MD) at an arbitrary position into a size of 10 mm×15 mm. The PE film is then removed. The resulting photosensitive resin laminate, along with the PET film thereon, is placed on a transparent glass with the surface of the photosensitive laminate facing the transparent glass. This assembly is then placed in a laminator and pressed under the following conditions: lamination rate of 0.5 m/min, lamination pressure of 3.0 kg/cm², and lamination temperature of 25° C. Subsequently, the PET film is removed, and the photosensitive resin laminate, along with the glass, is placed on a black flat substrate and exposed to light until the exposure energy reaches 100 mJ/cm². A 30° C. 1% Na₂CO₃ aqueous solution is used as a developer, and the photosensitive resin laminate, along with the glass, is immersed in the developer for 10 minutes. After development, the photosensitive resin laminate, along with the glass, is taken out, washed with pure water for 10 seconds, and then dried with air. An arbitrary area of 5 cm×5 cm in the center region of the glass is chosen for inspection. This area is divided to 100 subareas of 5 mm×5 mm and the subareas are inspected sequentially under a microscope with a 10× objective lens and a 10× eyepiece lens for bubbles. The number of bubbles, whose major axis is longer than 0.5 times the total thickness of the photosensitive resin laminate, is recorded.

### [Wrinkle Test of the Photosensitive Resin Laminate]

The prepared composite laminate is wound into a slit roll with a length of 30 m and a width of 300 mm and is placed at a temperature of 23° C. to 27° C. for 16 hours. Subsequently, a 5 m length of the composite laminate is pulled out from the slit roll, and the PE protective film of the composite laminate is peeled off. The surface of the photosensitive resin laminate is then visually inspected, recording the number of wrinkles with a length of 10 mm or more and a width of 1 mm or more within a range of 3 m to 5 m of the photosensitive resin laminate. If no wrinkles with a length of 10 mm or more and a width of 1 mm or more are found, it indicates excellent storage properties and operability of the photosensitive resin laminate.

### [100-Grid Adhesion Test of the Photosensitive Resin Film]

The 100-grid adhesion test of the photosensitive resin laminate is conducted according to ASTM D3359 in the following manner. A copper clad laminate with a thickness of 1.6 mm (available form Chang Chun Plastics Co., Ltd.; model: CCP-308) is prepared, wherein the copper foil of the copper clad laminate has a thickness of 35 μm. The copper clad laminate is subjected to brush grinding using a #320 non-woven brush wheel and a #600 non-woven brush wheel, and the temperature of the surface of the copper foil of the copper clad laminate is adjusted to 50° C. The PE film on the surface of the prepared composite laminate is peeled off, and then the photosensitive resin laminate, along with the PET film, is stacked on the surface of the copper foil in a manner, with the photosensitive resin laminate facing the surface of the copper foil of the copper clad laminate. The stack is then laminated with a laminator to provide a sample, using a lamination temperature of 80° C., a lamination pressure of 3.0 kg/cm², and a lamination rate of 2.0 m/min. The PET film on the sample is peeled off, and the photosensitive resin laminate of the sample is cut into 100 grids of 10×10 squares with a spacing of 1 mm to 1.2 mm using a blade. A transparent tape produced by the 3M company (model: 3M Transparent 600) is then adhered to the surface of the photosensitive resin laminate at the grids, then quickly peeled off at a 45-degree angle with respect to the substrate. The percentage of grids where the photosensitive resin laminate is peeled off relative to the total grids is calculated and recorded. A lower percentage indicates better adhesion of the photosensitive resin laminate to the copper clad laminate.

### 3.2. Preparation Methods

### 3.2.1. Synthesis of Alkali-Soluble Polymer

Carboxyl-containing acrylic acid-based polymers were prepared as the alkali-soluble polymers according to Synthesis Examples 1-7 below.

### Synthesis Example 1

For the co-polymerization monomers, a solution a1 was prepared by mixing 15 g of methacrylic acid, 60 g of methyl methacrylate, and 25 g of butyl acrylate with 1.8 g of azobisisoheptylnitrile. Separately, a solution b1 was prepared by dissolving 0.7 g of azobisisoheptylnitrile in 20 g of ethyl acetate.

A flask equipped with a stirrer, a reflux cooler, a thermometer, and a pipette was prepared. Then, 80 g of ethyl acetate was added into the flask and heated to 70° C. Subsequently, solution a1 was added dropwise into the flask at a constant rate over 3 hours, and the solution in the flask was maintained at a temperature of 70° C. and stirred for 2 hours. While continuously maintaining the temperature of the solution in the flask at 70° C., solution b1 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer A (also referred to as “polymer A” hereinafter), which has a weight average molecular weight of 55,000 and a solid content of 50 wt %.

### Synthesis Example 2

For the co-polymerization monomers, a solution a2 was prepared by mixing 15 g of methacrylic acid, 65 g of methyl methacrylate, and 20 g of butyl acrylate with 0.8 g of azobisisoheptylnitrile to prepare. Separately, a solution b2 was prepared by dissolving 0.5 g of azobisisoheptylnitrile in 20 g of methyl acetate.

A flask equipped with a stirrer, a reflux cooler, a thermometer, and a pipette was prepared. Then, 102.2 g of methyl acetate was added into the flask and heated to 70° C. Subsequently, solution a2 was added dropwise into the flask at a constant rate over 3 hours, and the solution in the flask was maintained at a temperature of 70° C. and stirred for 2 hours. While continuously maintaining the temperature of the solution in the flask at 70° C., solution b2 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer B (also referred to as “polymer B” hereinafter), which has a weight average molecular weight of 65,000 and a solid content of 45 wt %.

### Synthesis Example 3

For the co-polymerization monomers, a solution a3 was prepared by mixing 20 g of methacrylic acid, 40 g of methyl methacrylate, and 40 g of 2-ethylhexyl acrylate with 1.2 g of azobisisoheptylnitrile to prepare. Separately, a solution b3 was prepared by dissolving 0.5 g of azobisisoheptylnitrile in 20 g of acetone.

A flask equipped with a stirrer, a reflux cooler, a thermometer, and a pipette was prepared. Then, 80 g of acetone was added into the flask and heated to 70° C. Subsequently, solution a3 was added dropwise into the flask at a constant rate over 3 hours, and the solution in the flask was maintained at a temperature of 70° C. and stirred for 2 hours. While continuously maintaining the temperature of the solution in the flask at 70° C., solution b3 was added dropwise into the flask at a constant rate over 0.5 hours, and the solution in the flask was maintained at a temperature of 70° C. and stirred for 6 hours. Afterwards, the solution in the flask was heated to 90° C. and stirred for 4 hours to complete the reaction. After the reaction was completed, the resultant was cooled to room temperature to obtain a carboxyl-containing acrylic acid-based polymer C (also referred to as “polymer C” hereinafter), which has a weight average molecular weight of 55,000 and a solid content of 50 wt %.

### Synthesis Example 4

For the co-polymerization monomers, a solution a4 was prepared by mixing 20 g of methacrylic acid, 60 g of methyl methacrylate, and 20 g of butyl acrylate with 1 g of azobisisoheptylnitrile to prepare. Separately, a solution b4 was prepared by dissolving 0.5 g of azobisisoheptylnitrile in 20 g of methyl ethyl ketone.

A flask equipped with a stirrer, a reflux cooler, a thermometer, and a pipette was prepared. Then, 80 g of methyl ethyl ketone was added into the flask and heated to 70° C. Subsequently, solution a4 was added dropwise into the flask at a constant rate over 4 hours, and the solution in the flask was maintained at a temperature of 70° C. and stirred for 2 hours. While continuously maintaining the temperature of the solution in the flask at 70° C., solution b4 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer D (also referred to as “polymer D” hereinafter), which has a weight average molecular weight of 50,000 and a solid content of 50 wt %.

### Synthesis Example 5

For the co-polymerization monomers, a solution a5 was prepared by mixing 20 g of methacrylic acid, 60 g of methyl methacrylate, and 20 g of butyl acrylate with 1 g of azobisisoheptylnitrile. Separately, a solution b5 was prepared by dissolving 0.5 g of azobisisoheptylnitrile in a mixed solution of 10 g of propylene glycol methyl ether (PGME) and 10 g of ethyl acetate.

A flask equipped with a stirrer, a reflux cooler, a thermometer, and a pipette was prepared. Then, a mixed solution of 40 g of propylene glycol methyl ether and 40 g of ethyl acetate was added into the flask and heated to 70° C. Subsequently, solution a5 was added dropwise into the flask at a constant rate over 3 hours, and the solution in the flask was maintained at a temperature of 70° C. and stirred for 2 hours. While continuously maintaining the temperature of the solution in the flask at 70° C., solution b5 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer E (also referred to as “polymer E” hereinafter), which has a weight average molecular weight of 50,000 and a solid content of 50 wt %.

### Synthesis Example 6

For the co-polymerization monomers, a solution a6 was prepared by mixing 15 g of acrylic acid, 65 g of methyl methacrylate, and 20 g of hydroxyethyl methacrylate with 1 g of azobisisoheptylnitrile. Separately, a solution b6 was prepared by dissolving 0.5 g of azobisisoheptylnitrile was dissolved in a mixed solution of 4 g of ethanol and 16 g of ethyl acetate.

A flask equipped with a stirrer, a reflux cooler, a thermometer, and a pipette was prepared. Then, a mixed solution of 16 g of ethanol and 64 g of ethyl acetate was added into the flask and heated to 70° C. Subsequently, solution a6 was added dropwise into the flask at a constant rate over 3 hours, and the solution in the flask was maintained at a temperature of 70° C. and stirred for 2 hours. While continuously maintaining the temperature of the solution in the flask at 70° C., solution b6 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer F (also referred to as “polymer F” hereinafter), which has a weight average molecular weight of 50,000 and a solid content of 50 wt %.

### Synthesis Example 7

For the co-polymerization monomers, a solution a7 was prepared by mixing 20 g of methyl acrylic acid, 45 g of methyl methacrylate, and 35 g of 2-ethylhexyl acrylate with 1.9 g of azobisisoheptylnitrile. Separately, a solution b7 was prepared by dissolving 0.5 g of azobisisoheptylnitrile in a mixed solution of 2 g of methanol and 18 g of methyl acetate.

A flask equipped with a stirrer, a reflux cooler, a thermometer, and a pipette was prepared. Then, a mixed solution of 8 g of methanol and 72 g of methyl acetate was added into the flask and heated to 70° C. Subsequently, solution a7 was added dropwise into the flask at a constant rate over 3 hours, and the solution in the flask was maintained at a temperature of 70° C. and stirred for 2 hours. While continuously maintaining the temperature of the solution in the flask at 70° C., solution b7 was added dropwise into the flask at a constant rate over 0.5 hours, and the solution in the flask was maintained at a temperature of 70° C. and stirred for 5 hours. Afterwards, the solution in the flask was heated to 90° C. and stirred for 5 hours to complete the reaction. After the reaction was completed, the resultant was cooled to room temperature to obtain a carboxyl-containing acrylic acid-based polymer G (also referred to as “polymer G” hereinafter), which has a weight average molecular weight of 45,000 and a solid content of 50 wt %.

### 3.2.2. Preparation of Photosensitive Solution

The information about the raw materials used in the following preparation of photosensitive solutions is shown in Table 1 below.

TABLE 1

| Raw materials | Description |
|---|---|
| Polymer A | Alkali-soluble polymer: carboxyl-containing |
| | acrylic acid-based polymer A prepared in |
| | Synthesis Example 1 |
| Polymer B | Alkali-soluble polymer: carboxyl-containing |
| | acrylic acid-based polymer B prepared in |
| | Synthesis Example 2 |
| Polymer C | Alkali-soluble polymer: carboxyl-containing |
| | acrylic acid-based polymer C prepared in |
| | Synthesis Example 3 |
| Polymer D | Alkali-soluble polymer: carboxyl-containing |
| | acrylic acid-based polymer D prepared in |
| | Synthesis Example 4 |
| Polymer E | Alkali-soluble polymer: carboxyl-containing |
| | acrylic acid-based polymer E prepared in |
| | Synthesis Example 5 |
| Polymer F | Alkali-soluble polymer: carboxyl-containing |
| | acrylic acid-based polymer F prepared in |
| | Synthesis Example 6 |
| Polymer G | Alkali-soluble polymer: carboxyl-containing |
| | acrylic acid-based polymer G prepared in |
| | Synthesis Example 7 |
| Bis-A 10EO DMA | Component of ethylenically unsaturated |
| | compound: ethoxylated bisphenol-A |
| | dimethacrylate, CAS number: 41637-38-1 |
| TMPTA | Component of ethylenically unsaturated |
| | compound: trimethylolpropane triacrylate, |
| | CAS number: 15625-89-5 |
| HABI; BCIM | Photopolymerization initiator: imidazole-based |
| | compound, CAS number: 7189-82-4 |
| EABF | Photopolymerization initiator: ketone-based |
| | compound, CAS number: 90-93-7 |
| LCV | Additive, CAS number: 603-48-5 |
| NPG | Additive, CAS number: 103-01-5 |
| 2-mercaptobenzimidazole | Additive, CAS number: 583-39-1 |
| C.I. 42040 | Dye: brilliant green, a bisulfate salt, CAS |
| | number: 633-03-4 |
| THF | Solvent: tetrahydrofuran, CAS number: |
| | 109-99-9 |

According the components and proportions shown in Table 2, the respective photopolymerization initiator, additive, and THF solvent were mixed and stirred for 30 minutes to form a mixed solution. Subsequently, the respective carboxyl-containing acrylic acid-based polymer prepared in the Synthesis Examples and a component of ethylenically unsaturated compound(s) were added to the mixed solution and stirred for 1 hour, thereby obtaining the photosensitive solutions A to H.

TABLE 2

| Unit: parts by | Photosensitive | Photosensitive | Photosensitive | Photosensitive | Photosensitive | Photosensitive | Photosensitive | Photosensitive |
|---|---|---|---|---|---|---|---|---|
| weight | solution A | solution B | solution C | solution D | solution E | solution F | solution G | solution H |
| Polymer A | 200 | | | | | | | 200 |
| Polymer B | | 222 | | | | | | |
| Polymer C | | | 200 | | | | | |
| Polymer D | | | | 200 | | | | |
| Polymer E | | | | | 200 | | | |
| Polymer F | | | | | | 200 | | |
| Polymer G | | | | | | | 200 | |
| Bis-A 10EO | 45 | 45 | 45 | 45 | 40 | 45 | 35 | |
| DMA | | | | | | | | |
| TMPTA | | | | | 5 | | 10 | 8 |
| HABI; BCIM | 3 | 3 | 3 | 3 | 3 | 3 | 3.2 | 3.2 |
| EABF | 3 | 3 | 3 | 3 | 3 | 3 | 0.03 | 0.03 |
| LCV | | | | | | | 0.1 | 0.1 |
| NPG | | | | | | | 0.01 | 0.01 |
| 2-mercapto- | | | | | | | 0.01 | 0.01 |
| benzimidazole | | | | | | | | |
| C.I.42040 | 0.01 | 0.01 | 0.01 | 0.01 | 0.01 | 0.01 | 0.01 | 0.01 |
| THF | 10 | 10 | 10 | 10 | 10 | 10 | 10 | 10 |

### 3.2.3. Preparation of Photosensitive Resin Laminate

The photosensitive resin laminates of Examples E1 to E12 and Comparative Examples CE1 to CE15 were prepared to a desired thickness according to Tables 3-1 to 3-3, respectively. Specifically, the obtained photosensitive solution was coated onto a PET film with a Kodaira wire-wound rod, and the coated photosensitive solution was dried in an oven to form a photosensitive resin layer on the PET film. Subsequently, a PE film was stacked on the surface of the photosensitive resin layer that was not in contact with the PET film, thereby obtaining the photosensitive resin layers 1, 2, 3, and 4, each of which was covered on both surfaces.

The PE film was removed from the photosensitive resin layer 1, and the PET film was removed from the photosensitive resin layer 2. Then, the photosensitive resin layer 1 and the photosensitive resin layer 2 were pressed together with the surfaces of the photosensitive resin layers facing each other, resulting in a photosensitive resin laminate comprising the photosensitive resin layer 1 and the photosensitive resin layer 2.

The PE film was removed from the photosensitive resin layer 1 and the PET film was removed from the photosensitive resin layer 2. Then, the photosensitive resin layer 1 and the photosensitive resin layer 2 were pressed together with the surfaces of the photosensitive resin layers facing each other. Subsequently, the PE film was removed from the photosensitive resin layer 2, and the PET film was removed from the photosensitive resin layer 3. Then, the photosensitive resin layer 3 was adhered with its surface facing the surface of the photosensitive resin layer 2 not adhered to the photosensitive resin layer 1 and pressed together, resulting in a photosensitive resin laminate comprising the photosensitive resin layer 1, the photosensitive resin layer 2 and the photosensitive resin layer 3.

The PE film was removed from the photosensitive resin layer 1, and the PET film was removed from the photosensitive resin layer 2. Then, the photosensitive resin layer 1 and the photosensitive resin layer 2 were pressed together with the surfaces of the photosensitive resin layers facing each other. Subsequently, the PE film was removed from the photosensitive resin layer 2, and the PET film was removed from the photosensitive resin layer 3. Then, the photosensitive resin layer 3 was adhered with its surface facing the surface of the photosensitive resin layer 2 not adhered to the photosensitive resin layer 1. Further, the PE film was removed from the photosensitive resin layer 3, and the PET film was removed from the photosensitive resin layer 4. Then, the photosensitive resin layer 4 was adhered with its surface facing the surface of the photosensitive resin layer 3 not adhered to the photosensitive resin layer 2 and pressed together, resulting in a photosensitive resin laminate comprising the photosensitive resin layer 1, the photosensitive resin layer 2, the photosensitive resin layer 3 and the photosensitive resin layer 4.

TABLE 3-1

| | | E1 | E2 | E3 | E4 | E5 | E6 | E7 | E8 | E9 | E10 | E11 | E12 |
|---|---|---|---|---|---|---|---|---|---|---|---|---|---|
| Photosensitive | Photosensitive | A | A | B | A | A | A | C | A | A | D | E | F |
| resin layer 1 | solution | | | | | | | | | | | | |
| | Thickness | 50 | 200 | 300 | 250 | 280 | 300 | 100 | 150 | 120 | 300 | 300 | 300 |
| | (μm) | | | | | | | | | | | | |
| Photosensitive | Photosensitive | A | A | B | A | A | A | C | B | B | D | E | G |
| resin layer 2 | solution | | | | | | | | | | | | |
| | Thickness | 50 | 200 | 300 | 250 | 280 | 300 | 100 | 150 | 120 | 300 | 300 | 300 |
| | (μm) | | | | | | | | | | | | |
| Photosensitive | Photosensitive | | | | | | | C | C | C | | | |
| resin layer 3 | solution | | | | | | | | | | | | |
| | Thickness | | | | | | | 100 | 150 | 120 | | | |
| | (μm) | | | | | | | | | | | | |
| Photosensitive | Photosensitive | | | | | | | | A | A | | | |
| resin layer 4 | solution | | | | | | | | | | | | |
| | Thickness | | | | | | | | 150 | 120 | | | |
| | (μm) | | | | | | | | | | | | |

| | | | | | | | | | | | | |
|---|---|---|---|---|---|---|---|---|---|---|---|---|
| Total thickness (μm) | 100 | 400 | 600 | 500 | 560 | 600 | 300 | 600 | 480 | 600 | 600 | 600 |

TABLE 3-2

| | | CE1 | CE2 | CE3 | CE4 | CE5 | CE6 | CE7 | CE8 | CE9 | CE10 | CE11 | CE12 |
|---|---|---|---|---|---|---|---|---|---|---|---|---|---|
| Photosensitive | Photosensitive | A | B | C | A | A | C | C | D | E | F | H | D |
| resin layer 1 | solution | | | | | | | | | | | | |
| | Thickness | 1000 | 800 | 600 | 500 | 400 | 300 | 700 | 500 | 600 | 700 | 30 | 50 |
| | (μm) | | | | | | | | | | | | |
| Photosensitive | Photosensitive | | | | | | | | | | | | |
| resin layer 2 | solution | | | | | | | | | | | | |
| | Thickness | | | | | | | | | | | | |
| | (μm) | | | | | | | | | | | | |
| Photosensitive | Photosensitive | | | | | | | | | | | | |
| resin layer 3 | solution | | | | | | | | | | | | |
| | Thickness | | | | | | | | | | | | |
| | (μm) | | | | | | | | | | | | |
| Photosensitive | Photosensitive | | | | | | | | | | | | |
| resin layer 4 | solution | | | | | | | | | | | | |
| | Thickness | | | | | | | | | | | | |
| | (μm) | | | | | | | | | | | | |

| | | | | | | | | | | | | |
|---|---|---|---|---|---|---|---|---|---|---|---|---|
| Total thickness (μm) | 1000 | 800 | 600 | 500 | 400 | 300 | 700 | 500 | 600 | 700 | 30 | 50 |

TABLE 3-3

| | | CE13 | CE14 | CE15 |
|---|---|---|---|---|
| Photosensitive | Photosensitive | B | G | D |
| resin layer 1 | solution | | | |
| | Thickness | 3 | 300 | 400 |
| | (μm) | | | |
| Photosensitive | Photosensitive | B | | H |
| resin layer 2 | solution | | | |
| | Thickness | 3 | | 200 |
| | (μm) | | | |
| Photosensitive | Photosensitive | | | |
| resin layer 3 | solution | | | |
| | Thickness | | | |
| | (μm) | | | |
| Photosensitive | Photosensitive | | | |
| resin layer 4 | solution | | | |
| | Thickness | | | |
| | (μm) | | | |

| | | | |
|---|---|---|---|
| Total thickness (μm) | 6 | 300 | 600 |

### 3.3. Testing of Photosensitive Resin Laminate

The properties of the photosensitive resin laminates or photosensitive resin layers of Examples E1 to E12 and Comparative Examples CE1 to CE15, including number of layers of the photosensitive resin laminate, calculation result of the gas chromatography, bubbles, wrinkles and 100-grid adhesion properties, were tested according to the aforementioned testing methods. The results are tabulated in Tables 4-1 to 4-3.

TABLE 4-1

| | E1 | E2 | E3 | E4 | E5 | E6 | E7 | E8 | E9 | E10 | E11 | E12 |
|---|---|---|---|---|---|---|---|---|---|---|---|---|
| Number of layers | 2 | 2 | 2 | 2 | 2 | 2 | 3 | 4 | 4 | 2 | 2 | 2 |
| of photosensitive | | | | | | | | | | | | |
| resin laminate | | | | | | | | | | | | |
| Calculation result | 0.10 | 3.13 | 5.00 | 3.50 | 4.98 | 7.00 | 0.83 | 1.82 | 1.50 | 4.50 | 4.84 | 4.62 |
| of gas | | | | | | | | | | | | |
| chromatography | | | | | | | | | | | | |
| Number of | 0 | 0 | 0 | 0 | 0 | 0 | 0 | 0 | 0 | 0 | 0 | 0 |
| bubbles | | | | | | | | | | | | |
| Number of | 0 | 0 | 0 | 0 | 0 | 0 | 0 | 0 | 0 | 0 | 0 | 0 |
| wrinkles | | | | | | | | | | | | |
| 100-grid | <5% | <5% | <5% | <5% | <5% | <5% | <5% | <5% | <5% | <5% | <5% | <5% |
| peeled-off | | | | | | | | | | | | |
| percentage | | | | | | | | | | | | |

TABLE 4-2

| | CE1 | CE2 | CE3 | CE4 | CE5 | CE6 | CE7 | CE8 | CE9 | CE10 | CE11 | CE12 |
|---|---|---|---|---|---|---|---|---|---|---|---|---|
| Number of | 1 | 1 | 1 | 1 | 1 | 1 | 1 | 1 | 1 | 1 | 1 | 1 |
| layers of | | | | | | | | | | | | |
| photosensitive | | | | | | | | | | | | |
| resin laminate | | | | | | | | | | | | |
| Calculation | 11.20 | 9.60 | 9.32 | 8.84 | 8.75 | 8.32 | 11.04 | 9.23 | 9.82 | 10.95 | 0.06 | 0.09 |
| result of gas | | | | | | | | | | | | |
| chromatography | | | | | | | | | | | | |
| Number of | 18 | 11 | 13 | 8 | 6 | 5 | 7 | 9 | 13 | 22 | 3 | 5 |
| bubbles | | | | | | | | | | | | |
| Number of | 10 | 11 | 5 | 3 | 4 | 2 | 4 | 8 | 11 | 25 | 0 | 1 |
| wrinkles | | | | | | | | | | | | |
| 100-grid | <5% | <5% | <5% | <5% | <5% | <5% | <5% | <5% | <5% | <5% | >65% | 5%-15% |
| peeled-off | | | | | | | | | | | | |
| percentage | | | | | | | | | | | | |

TABLE 4-3

| | CE13 | CE14 | CE15 |
|---|---|---|---|
| Number of layers | 2 | 1 | 2 |
| of photosensitive | | | |
| resin laminate | | | |
| Calculation result | 0.04 | 3.30 | 9.80 |
| of gas | | | |
| chromatography | | | |
| Number of | 2 | 9 | 8 |
| bubbles | | | |
| Number of | 0 | 1 | 10 |
| wrinkles | | | |
| 100-grid | >65% | <5% | <5% |
| peeled-off | | | |
| percentage | | | |

As shown in Tables 4-1 to 4-3, the photosensitive resin laminates of the present application do not contain bubbles as defects and do not exhibit wrinkles, indicating that the photosensitive resin laminates have good operability and storage properties. Additionally, the photosensitive resin laminates of Examples E1 to E12 demonstrate low peeling-off percentages (<5%) in the 100-grid test, indicating good adhesion to copper clad laminate.

In contrast, the photosensitive resin laminates of Comparative Examples CE1 to CE10 and CE15 exhibit bubble defects and wrinkles, indicating poor operability and storage properties, because the calculation results of the gas chromatography for these photosensitive resin laminates are higher than the specified range (higher than 7.0%). The photosensitive resin laminates of Comparative Examples CE11 to CE13 exhibit bubble defects and show poor adhesion because the calculation results of the gas chromatography for these photosensitive resin laminates are lower than the specified range (lower than 0.1%). Particularly, although Comparative Example CE13 has a photosensitive resin laminate structure, it still cannot provide the inventive efficacy due to a calculation result of gas chromatography falling below the specified range. Although Comparative Example CE15 has a photosensitive resin laminate structure and a total thickness of 600 μm, it still cannot provide the inventive efficacy due to a calculation result of gas chromatography exceeding the specified range. This highlights the importance of the gas chromatography technical feature specified in the present application.

On the other hand, Comparative Example CE14 shows that even if the technical feature of gas chromatography specified in the present application is satisfied, defects such as bubbles and wrinkles may still occur if the photosensitive resin film lacks a laminate structure. This emphasizes the importance of simultaneously having a photosensitive resin laminate structure and meeting the technical feature of gas chromatography specified in the present application.

Furthermore, the comparison between Example 4 and Comparative Example CE4, Example E2 and Comparative Example CE5, Example E7 and Comparative Example CE6 and Example E11 and Comparative Example CE9 show that, even with identical total thickness, the comparative examples lacking two or more photosensitive resin layers may fail to satisfy the aforementioned formula, resulting in the presence of numerous bubbles and wrinkles. This highlights the importance of the technical feature of having a photosensitive resin laminate structure.

The above examples illustrate the principle and efficacy of the present application and show its inventive features. People skilled in this field may proceed with various modifications and replacements based on the disclosures and suggestions of the application as described without departing from the principle thereof. Therefore, the scope of protection of the present application is as defined in the claims as appended.

1. A photosensitive resin laminate, which consists of two or more photosensitive resin layers and comprises a second component, wherein:
when the photosensitive resin laminate is characterized by gas chromatography with added toluene as an internal standard, an elution peak of the second component is at a retention time ranging from 0.55 min to 1.30 min, an elution peak of the added toluene is at a retention time ranging from 1.32 min to 1.65 min, and the following formula is satisfied:
$$\frac{\frac{\begin{matrix}Area of the elution peak \\ of the second component\end{matrix}}{\begin{matrix}Area of the elution peak \\ of the added toluene\end{matrix}} \times \begin{matrix}Amount of the \\ added toluene\end{matrix}}{Mass of the photosensitive resin laminate} \times 100 \% = 0.1 \% - 7. \% ,$$
wherein the amount of the added toluene and the mass of the photosensitive resin laminate are in grams (g);
the photosensitive resin laminate has a total thickness of 100 μm to 600 μm; and
the second component comprises at least one of an inert ester, ketone, ether, and alcohol.

2. The photosensitive resin laminate of claim 1, wherein the gas chromatography is performed by dissolving the photosensitive resin laminate in propylene glycol methyl ether with added toluene as an internal standard to form a solution, and testing the solution under the following conditions: a stainless steel column with a column length of 3 meters, an outer diameter of ⅛ inches and a column wall thickness of 0.02 inches is used; a porous polymer stationary phase is used as a filler; helium with a flow rate of 20 mL/min and a supply pressure of 5 kgf/cm² serves as a carrier gas; a stepwise heating condition is applied, which sequentially includes maintaining at 80° C. for 0.1 min, heating from 80° C. to 96° C. at a heating rate of 4° C./min, heating from 96° C. to 135° C. at a heating rate of 10° C./min, and maintaining at 135° C. for 2 min; a temperature at an injection port is 180° C.; an injection volume of the solution is 3 μL; and a thermal conductivity detector at 200° C. is used.

3. The photosensitive resin laminate of claim 1, wherein the two or more photosensitive resin layers each independently have a thickness of 50 μm to 300 μm.

4. The photosensitive resin laminate of claim 1, which consists of two to four photosensitive resin layers.

5. The photosensitive resin laminate of claim 2, which consists of two to four photosensitive resin layers.

6. The photosensitive resin laminate of claim 3, which consists of two to four photosensitive resin layers.

7. The photosensitive resin laminate of claim 1, wherein the two or more photosensitive resin layers are each independently dry films.

8. The photosensitive resin laminate of claim 2, wherein the two or more photosensitive resin layers are each independently dry films.

9. The photosensitive resin laminate of claim 3, wherein the two or more photosensitive resin layers are each independently dry films.

10. The photosensitive resin laminate of claim 1, wherein the two or more photosensitive resin layers each independently comprise:
(A) an alkali-soluble polymer;
(B) a component of ethylenically unsaturated compound(s); and
(C) a photopolymerization initiator.

11. The photosensitive resin laminate of claim 10, wherein the component (B) of ethylenically unsaturated compound(s) comprises one or more bifunctional acrylate-based compounds.

12. The photosensitive resin laminate of claim 11, wherein based on the weight of the component (B) of ethylenically unsaturated compound(s), the amount of the bifunctional acrylate-based compounds is 60 wt % or more.

13. The photosensitive resin laminate of claim 2, wherein the two or more photosensitive resin layers each independently comprise:
(A) an alkali-soluble polymer;
(B) a component of ethylenically unsaturated compound(s); and
(C) a photopolymerization initiator.

14. The photosensitive resin laminate of claim 13, wherein the component (B) of ethylenically unsaturated compound(s) comprises one or more bifunctional acrylate-based compounds.

15. The photosensitive resin laminate of claim 14, wherein based on the weight of the component (B) of ethylenically unsaturated compound(s), the amount of the bifunctional acrylate-based compounds is 60 wt % or more.

16. The photosensitive resin laminate of claim 3, wherein the two or more photosensitive resin layers each independently comprise:
(A) an alkali-soluble polymer;
(B) a component of ethylenically unsaturated compound(s); and
(C) a photopolymerization initiator.

17. The photosensitive resin laminate of claim 16, wherein the component (B) of ethylenically unsaturated compound(s) comprises one or more bifunctional acrylate-based compounds.

18. The photosensitive resin laminate of claim 17, wherein based on the weight of the component (B) of ethylenically unsaturated compound(s), the amount of the bifunctional acrylate-based compounds is 60 wt % or more.

19. A composite laminate, which comprises:
the photosensitive resin laminate of claim 1; and
a non-photosensitive resin film on at least one surface of the photosensitive resin laminate.

20. The composite laminate of claim 19, wherein the non-photosensitive resin film is selected from the group consisting of a polyethylene terephthalate film, a polyolefin film, and a composite thereof.
